(19) United States
(12) Patent Application Publication
(10) Pub. No.: US 2005/0045851 A1
(43) Pub. Date: Mar. 3, 2005

(54) Polymer catalyst for photovoltaic cell

(75) Inventors: Jin-An He, North Chelmsford, MA (US); Savvas Hadjikyriacou, Tingsboro, MA (US)

Correspondence Address: FISH & RICHARDSON PC, 225 FRANKLIN ST, BOSTON, MA, 02110, US

(73) Assignee: Konarka Technologies, Inc., Lowell, MA (US)

(21) Appl. No.: 10/897,268

(22) Filed: Jul. 22, 2004

Related U.S. Application Data
(60) Provisional application No. 60/495,302, filed on Aug. 15, 2003.

(51) Int. Cl. H01L 29/12; C04B 35/00

(52) U.S. Cl. 252/62.3 R; 136/252; 252/500

(57) ABSTRACT

Polymer catalysts for photovoltaic cells, as well as related compositions and methods, are disclosed.

### CROSS-REFERENCE TO RELATED APPLICATION

This application claims priority under 35 U.S.C. §119(e) to U.S. Provisional Patent Application Ser. No. 60/495,302, filed Aug. 15, 2003, and entitled “Polymer Catalyst for Photovoltaic Cell”, the contents of which are hereby incorporated by reference.

### TECHNICAL FIELD

The invention relates to polymer catalysts for photovoltaic cells, as well as related compositions and methods.

### BACKGROUND

Photovoltaic cells, sometimes called solar cells, can convert light, such as sunlight, into electrical energy. One type of photovoltaic cell is a dye-sensitized solar cell (DSSC).

Referring to FIG. 1, is a DSSC 100 includes a charge carrier layer 140 (e.g., including an electrolyte, such as an iodide/iodine solution) and a photosensitized layer 145 (e.g., including a semiconductor material, such as TiO₂ particles) disposed between an electrode 101 and a counter electrode 111. Photosensitized layer 145 also includes a photosensitizing agent, such as a dye. In general, the photosensitizing agent is capable of absorbing photons within a wavelength range of operation (e.g., within the solar spectrum). Electrode 101 includes a substrate 160 (e.g., a glass or polymer substrate) and an electrically conductive layer 150 (e.g., an ITO layer or tin oxide layer) disposed on an inner surface 162 of substrate 160. Counter electrode 111 includes a substrate 110, an electrically conductive layer 120 (e.g., ITO layer or tin oxide layer), and a platinum layer 130, which catalyzes a redox reaction in charge carrier layer 140. Electrically conductive layer 120 is disposed on an inner surface 112 of substrate 110, while catalyst layer 130 is disposed on a surface 122 of electrically conductive layer 120. Electrode 101 and counter electrode 111 are connected by wires across an external electrical load 170.

During operation, in response to illumination by radiation in the solar spectrum, DSSC 100 undergoes cycles of excitation, oxidation, and reduction that produce a flow of electrons across load 170. Incident light excites photosensitizing agent molecules in photosensitized layer 145. The photoexcited photosensitizing agent molecules then inject electrons into the conduction band of the semiconductor in layer 145, which leaves the photosensitizing agent molecules oxidized. The injected electrons flow through the semiconductor material, to electrically conductive layer 150, then to external load 170. After flowing through external load 170, the electrons flow to layer 120, then to layer 130 and subsequently to layer 140, where the electrons reduce the electrolyte material in charge carrier layer 140 at catalyst layer 130. The reduced electrolyte can then reduce the oxidized photosensitizing agent molecules back to their neutral state. The electrolyte in layer 140 can act as a redox mediator to control the flow of electrons from counter electrode 111 to working electrode 101. This cycle of excitation, oxidation, and reduction is repeated to provide continuous electrical energy to external load 170.

### SUMMARY

The invention relates to polymer catalysts for photovoltaic cells, as well as related compositions and methods.

In one aspect, the invention features a composition that includes a monomer capable of forming a polymer capable of catalyzing reduction of I₃⁻ to I⁻, a solvent and an acid. The acid has a pKa of about three or less.

In another aspect, the invention features a composition that includes a monomer capable of forming a polymer capable of catalyzing reduction of I₃⁻ to I⁻, a solvent and an acid. The composition contains at least about 0.01 molar acid.

In a further aspect, the invention features a method that includes disposing a composition on a surface. The composition includes a monomer capable of forming a polymer capable of catalyzing reduction of I₃⁻ to I⁻, a solvent, and an acid. The acid has a pKa of about three or less.

In one aspect, the invention features a method that includes disposing a composition on a surface. The composition includes a monomer capable of forming a polymer capable of catalyzing reduction of I₃⁻ to I⁻, a solvent, and an acid. The composition comprises at least 0.01 molar acid.

In another aspect, the invention features a method that includes coating an electrically conductive surface with a composition. The composition includes a monomer capable of forming a polymer capable of catalyzing reduction of I₃⁻ to I⁻, a solvent, and an acid.

In a further aspect, the invention features an article that includes two layers. One layer is formed of an electrically conductive material, and the other layer, which is disposed on the surface of the first layer, is formed of a polymer capable of catalyzing reduction of I₃⁻ to I⁻. The polymer remains disposed on the surface of the electrically conductive material after washing the second layer.

In one aspect, the invention features a photovoltaic cell that includes two electrodes. One of the electrodes includes an electrically conductive layer, a polymer capable of catalyzing reduction of I₃⁻ to I⁻ that is disposed on the electrically conductive layer. The photovoltaic cell also includes an electrolyte disposed between the two electrodes. The polymer remains disposed on the surface of the electrically conductive layer after washing the polymer.

Embodiments include one or more of the following aspects.

The acid can have a pKa of about three or less (e.g., about two or less, about one or less, about zero or less).

The acid can be an inorganic acid (e.g., hydrochloric acid, nitric acid, perchloric acid, chloric acid, hydrogen iodide, hydrogen bromide, and/or thiocyanic acid).

The acid can be an organic acid (e.g., trifluoromethanesulfonic acid, benzenesulfonic acid, methanesulphonic acid, p-toluenesulfonic acid, and/or tricyanomethane).

The composition can be at least about 0.01 molar acid (e.g., at least about 0.05 molar acid, at least about 0.1 molar acid) and/or about 0.2 molar or less acid.

The monomer can be a thiophene monomer (e.g., ethylene-dioxythiophene).

The polymer can be transparent.

The solvent can be a polar organic solvent (e.g., an alcohol, a sulphoxide, a sulphone, an amide or a nitrile). Examples of alcohols include methanol, ethanol, i-propanol, dichloromethane, dichloroethane, acetonitrile, dimethyl sulphoxide, sulfolane, methyl acetamide, and dimethyl formamide.

The solvent can be water.

The composition can further include an initiator capable of causing the monomer to react to form the polymer. The initiator can be an oxidant. Examples of oxidants include an iron (III) salt, H₂O₂, K₂Cr₂O₇, alkali metal persulphates, ammonium persulphates, alkali metal perborates, potassium permanganate and copper salts. Examples of iron (III) salts include FeCl₃, Fe(ClO₄)₃ and iron (III) salts of organic acids (e.g., iron (III) tosylate).

The ratio of the molar concentration of the monomer to the molar concentration of the initiator in the composition can be equal to or less than about five.

The transparent layer can include a mesh. The transparent layer can include ITO.

The method can include coating the composition on the surface (e.g., spin coating, dip coating, knife coating, bar coating, spray coating, roller coating, slot coating, gravure coating, or screen printing).

The method can include electrochemically depositing the polymer on the surface.

The method can include polymerizing the monomer after disposing the solution on the surface to form a polymer layer. Polymerizing can include heating the surface (e.g., above about 50° C., above about 100° C.) after disposing the solution on the surface.

The polymer layer can be less than about 100 nm thick (e.g., less than about 50 nm thick).

The method can include washing the polymer layer. The polymer layer can remain substantially adhered to the surface after washing. Washing can include exposing the layer to a washing solvent (e.g., a polar solvent, such as water, an alcohol or both). Washing can include agitating the surface while exposing the layer to the washing solvent.

The polymer can be a polythiophene (e.g., polyethylene-dioxythiophene).

Embodiments can provide one or more of the following advantages.

The compositions and methods disclosed herein may provide for improved adhesion between an electrically conducting layer and a polymeric catalytic layer. The methods and compositions may be compatible with web-based manufacturing processes for DSSC's. DSSC counter electrodes formed using methods and/or compositions may provide higher transparency than, for example, comparable counter electrodes formed from platinum. Such counter electrodes may also exhibit improved thermal stability compared to, for example, counter electrodes formed from platinum. DSSC's prepared using the disclosed methods and compositions may be manufactured more economically than other DSSC's.

The details of one or more embodiments of the invention are set forth in the accompanying drawings and the description below. Other features, objects, and advantages of the invention will be apparent from the description and drawings, and from the claims.

### DESCRIPTION OF DRAWINGS

FIG. 1 is a cross-sectional view of an embodiment of a photovoltaic cell.

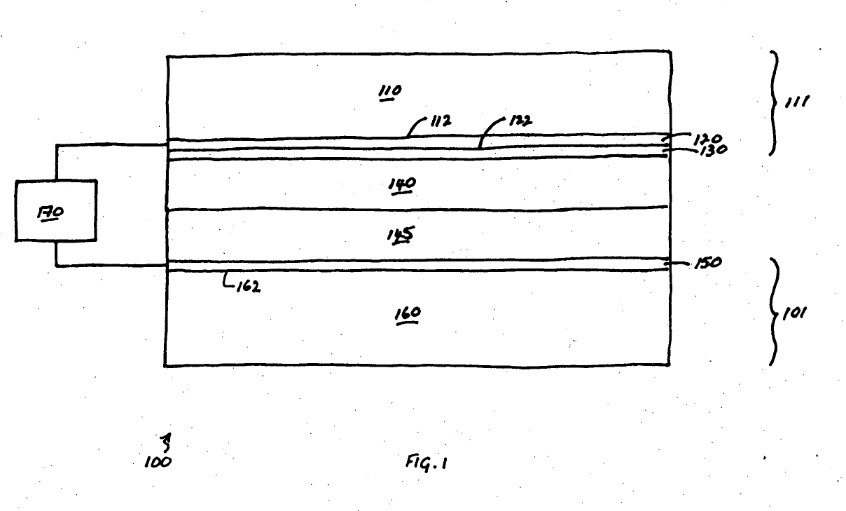

FIG. 2 is a cross-sectional view of another embodiment of a photovoltaic cell.

FIG. 3 is a cross-sectional view of an embodiment of a photovoltaic cell including a mesh electrode.

Like reference symbols in the various drawings indicate like elements.

### DETAILED DESCRIPTION

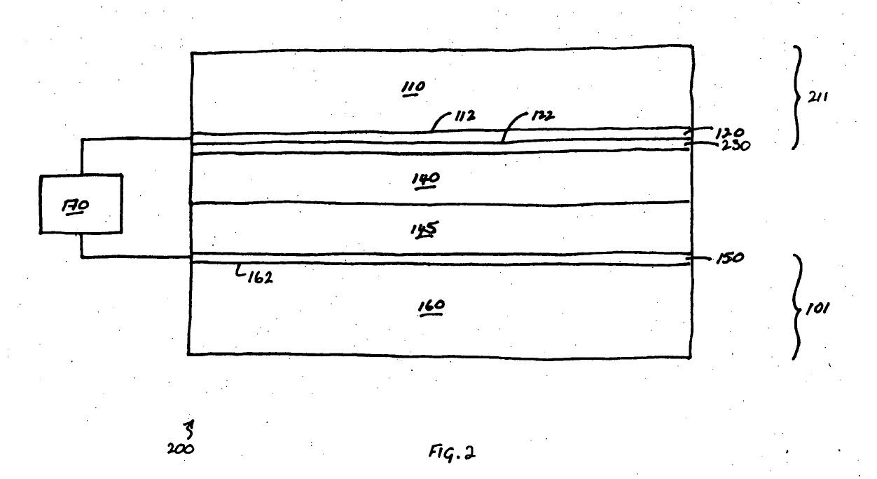

Referring to FIG. 2, a counter electrode 211 of a DSSC 200 includes a catalyst layer 230 having a polymer catalyst. The type of polymer generally depends on the redox system in charge carrier layer 140, and polymer catalysts are typically selected based on their ability to catalyze the redox reaction in charge carrier layer 140. Polymer catalysts can also be selected based on criteria such as, for example, their compatibility with manufacturing processes, long term stability, and optical properties.

One example of an electrolyte redox system contained in layer 140 is I⁻/I₃⁻, which can be provided as a solution of an iodide salt (e.g., lithium iodide) and iodine. An example of such a solution is 0.5 molar tertiary-butyl pyridine, 0.1 molar lithium iodide, 0.05 molar I₂ and 0.6 molar butylmethyl imidazolium iodide in acetonitrile/valeronitrile (1/1, v/v).

Polymers capable of catalyzing reduction of I₃⁻ to I⁻ include polythiophenes and polythiophene derivatives, such as poly(3,4-ethelynedioxythiophene) (PEDOT), poly(3-butylthiophene), and poly[3-(4-octylphenyl)thiophene], polypyrrole, polyaniline and their derivatives.

In general, catalyst layer 230 adheres well to surface 122 of layer 120. The adhesion between catalyst layer 230 and surface 122 can be sufficiently strong to withstand various processing steps and environmental factors the DSSC experiences during manufacture and use. One example of a process step is washing (described below). In general, the adhesion between catalyst layer 230 and surface 122 prevents catalyst layer 120 from delaminating from surface 122 during the washing process. Generally, the adhesion also prevents catalyst layer 230 from delaminating during subsequent coating steps and during lamination of the DSSC substrates (described below). In some embodiments, catalyst layer 230 exhibits good adhesion under conditions of high temperature (e.g., up to about 85° C.) and/or when exposed to relatively harsh chemical conditions (e.g., I⁻/I₃⁻ dissolved in an organic solvent or ionic liquid).

In some embodiments, adhesion between catalyst layer 230 and surface 122 is greater than adhesion between electrically conductive layer 120 and surface 112. For example, in such embodiments, a manual peel test performed on catalyst layer 230 will cause the electrically conductive layer 120 to delaminate from substrate surface 112, rather than catalyst layer 230 to delaminate from surface 122. One example of a manual peel test is to use a knife to make a cut in the coating film and attempt to peel or scratch the coating film from the substrate.

In general, the thickness of catalyst layer 230 can vary as desired. In some embodiments, catalyst layer can be relatively thin compared to the substrate 110, which can be microns, tens of microns, or hundreds of microns or more thick. For example, catalyst layer 230 can be less than about one micron thick (e.g., less than about 500 nm thick). In some embodiments, catalyst layer 230 is less than about 100 nm thick, such as less than about 50 nm thick (e.g., about 30 nm thick).

In some embodiments, catalyst layer 230 is transparent. As referred to herein, a transparent layer transmits at least about 60% (e.g., at least about 70%, at least about 75%, at least about 80%, at least about 85%) of incident energy at a wavelength or a range of wavelengths used during operation of the DSSC. Typically, the wavelength range of operation is within the solar spectrum (e.g., between about 380 nm and about 780 nm).

In some embodiments, catalyst layer 230 can transmit more incident energy at a given optical wavelength or a given range of optical wavelengths than a platinum catalyst layer that would provide a comparable level of catalysis in charge carrier layer 140.

Catalyst layer 230 can include other compounds in addition to the polymer catalyst (e.g., in addition to PEDOT), such as, for example, compounds that affect the mechanical, optical, and/or other physical properties of layer 230. As an example, in some embodiments, catalyst layer 230 can include a compound that changes the refractive index of the polymer catalyst (e.g., to reduce a refractive index mismatch between polymer catalyst layer 230 and electrically conductive layer 120 and/or charge carrier layer 140). As another example, in certain embodiments, catalyst layer 230 can include a compound, such as a cross-linker, that changes the mechanical properties of the polymer catalyst (e.g., to increase the rigidity of polymer catalyst layer 230).

Catalyst layer 230 can be applied to surface 122 using a variety of techniques.

In some embodiments, the polymer can be electrochemically deposited or coated on surface 122. During electrochemical deposition, substrate 110 can be placed in a bath containing a solution of a monomer and applying a voltage between electrically conductive layer 120 and another electrode. In some embodiments, the solution can include an acid. Methods of electrochemical deposition are described in “Fundamentals of Electrochemical Deposition,” by Milan Paunovic and Mordechay Schlesinger (Wiley-Interscience; November 1998), for example.

In certain embodiments, the polymer can be applied using methods that involve using a coating method, such as spin coating, dip coating, knife coating, bar coating, spray coating, roller coating, slot coating, gravure coating, screen printing, and/or ink-jetting. Coating methods can be used in both continuous and batch modes of manufacturing.

In some embodiments, a polymer catalyst is coated as a hot melt. In certain embodiments, a polymer is coated as a monomer (e.g., ethylene-dioxythiophene (EDOT)) which is subsequently polymerized. In some embodiments, the monomer is coated in solution onto surface 122 and subsequently polymerized to form polymer catalyst layer 230. In addition to the monomer and a suitable solvent, such solutions typically include an acid and an initiator for initiating polymerization of the monomer.

The percentage of monomer in the solvent can vary depending on the method of coating used to apply the monomer to surface 122, the type of solvent used, and the conditions under which surface 122 is coated (e.g., web velocity). For example, for a given web velocity, the percentage of monomer in the solution can be increased if a thicker catalyst layer is desired. In some embodiments, the solution can be less than about five percent (e.g., less than about three percent, one percent) by weight monomer.

A suitable solvent is a solvent capable of dissolving the monomer and initiator, and compatible with the acid (the acid and solvent should be miscible and should not result in an undesirable chemical reaction). Suitable solvents for thiophene monomers, for example, include many polar organic and inorganic solvents (the solvent molecules possess a permanent dipole moment). Examples of polar organic solvents include alcohols (e.g., methanol, ethanol, i-propanol), sulphoxides (e.g., dimethyl sulphoxide), sulphones (e.g., sulfolane), halogenated alkanes (e.g., dichloromethane, dichloroethane), amides (e.g., methyl acetamide, dimethyl formamide) and nitrites (e.g., acetonitrile). An example of a polar inorganic solvent is water.

Without wishing to be bound by theory, it is believed that the acid can provide improved adhesion between the catalyst layer 230 and surface 122. Suitable acids include organic acids and inorganic acids. Examples of inorganic acids include hydrochloric acid, nitric acid, perchloric acid, chloric acid, hydrogen iodide, hydrogen bromide, or thiocyanic acid. Examples of organic acids may include trifluoromethanesulfonic acid, benzenesulfonic acid, methanesulphonic acid, p-toluenesulfonic acid, or tricyanomethane.

In some embodiments, the acid can have a low pKa. For example, the acid can have a pKa less than about 3 (e.g., less than about 2, less than about 1, less than about zero, less than about −1, less than about −2, less than about −3).

Without wishing to be bound by theory, it is believed that the concentration of the acid should be sufficient to improve adhesion between the polymer and surface 122 during the time surface 122 is exposed to the acid. In addition to the type of acid and material forming electrically conducting layer 120, this can depend on various manufacturing process parameters, such as percent solids in the monomer solution, desired dry thickness of the coating, web speed, and drying temperature. In some embodiments, the acid has a concentration of between about 0.01 molar (“M”) and about 0.4 M (e.g., at least about 0.05 M, at least about 0.1 M, at most about 0.3 M, at most about 0.2 M).

In some embodiments, no acid is included in the coating solution. In such embodiments, surface 122 can be pretreated with an acid (e.g., bathed in an acid or coated with an acid) prior to coating with the monomer solution.

Polymerization of the coated monomer can be initiated in a variety of ways, such as chemically, thermally, electrically (e.g., electrochemically, or via an electron beam). Combinations of techniques can be used. In embodiments where polymerization is initiated chemically, the solution can include an initiator, such as a photoinitiator or an oxidant. Examples of oxidants suitable for polymerizing thiophene monomers include iron (III) salts, such as FeCl₃, Fe(ClO₄)₃, and/or iron (III) salts of organic acids (e.g., iron (III) tosylate). In addition to iron (III) salts, suitable oxidant initiators for thiophene monomers include H₂O₂, K₂Cr₂O₇, alkali metal persulphates, ammonium persulphates, alkali metal perborates, potassium permanganate and/or copper salts.

The relative amount of initiator in the solvent can vary depending on the amount of monomer and the desired degree of polymerization. A high concentration of initiator can result in a higher molecular weight of the resulting polymer. In some embodiments, the ratio of the molar concentration of the monomer to the molar concentration of the initiator in the composition is equal to or less than about five (e.g., from about 0.5 to about five, from about 0.5 to about two, from about 0.5 to about one).

In some embodiments, thiophene monomers, for example, are polymerized by heating in the presence of an oxidant. The polymerization temperature can vary, but should be below temperatures that would damage the substrate and/or polymer catalyst. In some embodiments, the coating is heated to a temperature of from about 50° C. to about 300° C., such from about 75° C. to about 150° C. (e.g., about 120° C.).

Generally, after polymerization, the coating is washed. Washing typically involves rinsing the polymer layer with a solvent (e.g., an alcohol, water, a combination of alcohol and water). The solvent may dissolve certain undesirable components from the coating (e.g., unreacted monomer and residual initiator) to substantially remove undesirable components from the polymer layer. Washing can include agitating (e.g., ultrasonically agitating) the layer to help flush these components. In embodiments where the polymer catalyst is coated in a continuous process, washing can involve running the coated web through a solvent bath or series of baths.

In some embodiments (e.g., with or without the use of an acid), surface 122 can be treated with other compounds to promote adhesion. For example, prior to applying the polymer catalyst, surface 122 can be coated with a cross-linking agent (e.g., a bifunctional silane or epoxy) that bonds to surface 122 and to the subsequently applied polymer.

Turning now to other components of DSSC 200, the composition and thickness of electrically conductive layer 120 is generally selected based on desired electrical conductivity, optical properties, and/or mechanical properties of the layer. In some embodiments, layer 120 is transparent. Examples of transparent conductors suitable for forming such a layer include certain metal oxides, such as indium tin oxide (ITO), tin oxide, and a fluorine-doped tin oxide. Electrically conductive layer 120 may be, for example, between about 100 nm and 500 nm thick, (e.g., between about 150 nm and 300 nm thick).

In embodiments where the acid in the solution used to apply the polymer catalyst to surface 122, surface 122 can be a roughened surface. In other words, the microscopic surface area of, e.g., a 1 cm by 1 cm portion of surface 122 is greater than a 1 cm by 1 cm portion of a non-roughened surface (e.g., more than about five percent greater, such as about 10 percent or more). The additional microscopic surface area can be provided by topographical features on the order of sub-microns to tens of microns in size formed as material is etched from layer 120 while it is in contact with the acid. Without wishing to be bound by theory, it is believed that roughening of surface 122 can enhance its adhesion to catalyst layer 230 because surface 122 presents a greater surface area with which the polymer forming catalyst layer 230 can bond.

In embodiments where counter electrode 211 is not transparent, electrically conductive layer 120 can be opaque (i.e., can transmit less than about 10% of the visible spectrum energy incident thereon). For example, layer 120 can be formed from a continuous layer of an opaque metal, such as copper, aluminum, indium, or gold.

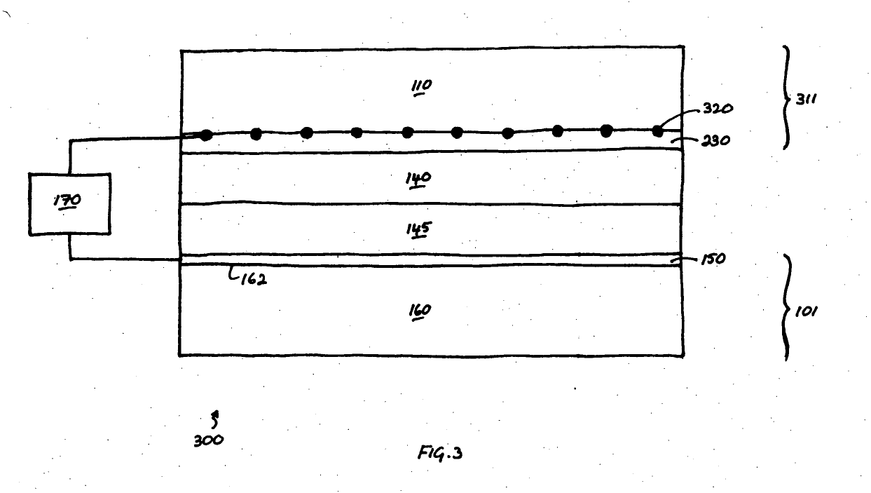

In some embodiments, electrically conductive layer 120 can include a discontinuous layer of a conductive material. For example, electrically conductive layer 120 can include an electrically conducting mesh. Referring to FIG. 3, a counter electrode 311 of a DSSC 300 includes a mesh electrode 320. Suitable mesh materials include metals, such as palladium, titanium, platinum, stainless steels and allows thereof. In some embodiments, the mesh material includes a metal wire. The electrically conductive mesh material can also include an electrically insulating material that has been coated with an electrically conducting material, such as a metal. The electrically insulating material can include a fiber, such as a textile fiber or optical fiber. Examples of fibers include synthetic polymeric fibers (e.g., nylons) and natural fibers (e.g., flax, cotton, wool, and silk). The mesh electrode can be flexible to facilitate, for example, formation of the DSSC by a continuous manufacturing process.

The mesh electrode may take a wide variety of forms with respect to, for example, wire (or fiber) diameters and mesh densities (i.e., the number of wires (or fibers) per unit area of the mesh). The mesh can be, for example, regular or irregular, with any number of opening shapes. Mesh form factors (such as, e.g., wire diameter and mesh density) can be chosen, for example, based on the conductivity of the wire (or fibers) of the mesh, the desired optical transmissivity, flexibility, and/or mechanical strength. Typically, the mesh electrode includes a wire (or fiber) mesh with an average wire (or fiber) diameter in the range from about one micron to about 400 microns, and an average open area between wires (or fibers) in the range from about 60% to about 95%.

Referring to both FIG. 2 and FIG. 3, substrate 110 can be formed from a mechanically-flexible material, such as a flexible polymer, or a rigid material, such as a glass. Examples of polymers that can be used to form a flexible substrate include polyethylene naphthalates (PEN), polyethylene terephthalates (PET), polyethyelenes, polypropylenes, polyamides, polymethylmethacrylate, polycarbonate, and/or polyurethanes. Flexible substrates can facilitate continuous manufacturing processes such as web-based coating and lamination.

The thickness of substrate 110 can vary as desired. Typically, substrate thickness and type are selected to provide mechanical support sufficient for the DSSC to withstand the rigors of manufacturing, deployment, and use. Substrate 110 can have a thickness of about 50 to 5,000 microns, such as, for example, about 100 to 1,000 microns.

In embodiments where the counter electrode is transparent, substrate 110 is formed from a transparent material. For example, substrate 110 can be formed from a transparent glass or polymer, such as a silica-based glass or a polymer, such as those listed above. In such embodiments, electrically conductive layer 120 should also be transparent.

Substrate 160 and electrically conductive layer 150 can be similar to substrate 110 and electrically conductive layer 120, respectively. For example, substrate 160 can be formed from the same materials and can have the same thickness as substrate 110. In some embodiments however, it may be desirable for substrate 160 to be different from 110 in one or more aspects. For example, where the DSSC is manufactured using a process that places different stresses on the different substrates, it may be desirable for substrate 160 to be more or less mechanically robust than substrate 110. Accordingly, substrate 160 may be formed from a different material, or may have a different thickness that substrate 110. Furthermore, in embodiments where only one substrate is exposed to an illumination source during use, it is not necessary for both substrates and/or electrically conducting layers to be transparent. Accordingly, one of substrates and/or corresponding electrically conducting layer can be opaque.

As discussed previously, charge carrier layer 140 includes a material that facilitates the transfer of electrical charge from a ground potential or a current source to photosensitized layer 145. A general class of suitable charge carrier materials include solvent-based liquid electrolytes, polyelectrolytes, polymeric electrolytes, solid electrolytes, n-type and p-type transporting materials (e.g., conducting polymers) and gel electrolytes. Other choices for charge carrier media are possible. For example, the charge carrier layer can include a lithium salt that has the formula LiX, where X is an iodide, bromide, chloride, perchlorate, thiocyanate, trifluoromethyl sulfonate, or hexafluorophosphate. The charge carrier media typically includes a redox system. Suitable redox systems may include organic and/or inorganic redox systems. Examples of such systems include cerium(III) sulphate/cerium(IV), sodium bromide/bromine, lithium iodide/iodine, Fe²⁺/Fe³⁺, Co²⁺/Co³⁺, and viologens. Furthermore, an electrolyte solution may have the formula MᵢXⱼ, where i and j are greater than or equal to one, where X is an anion, and M is lithium, copper, barium, zinc, nickel, a lanthanide, cobalt, calcium, aluminum, or magnesium. Suitable anions include chloride, perchlorate, thiocyanate, trifluoromethyl sulfonate, and hexafluorophosphate.

In some embodiments, the charge carrier media includes a polymeric electrolyte. For example, the polymeric electrolyte can include poly(vinyl imidazolium halide) and lithium iodide and/or polyvinyl pyridinium salts. In embodiments, the charge carrier media can include a solid electrolyte, such as lithium iodide, pyridinium iodide, and/or substituted imidazolium iodide.

The charge carrier media can include various types of polymeric polyelectrolytes. For example, suitable polyelectrolytes can include between about 5% and about 95% (e.g., 5-60%, 5-40%, or 5-20%) by weight of a polymer, e.g., an ion-conducting polymer, and about 5% to about 95% (e.g., about 35-95%, 60-95%, or 80-95%) by weight of a plasticizer, about 0.05 M to about 10 M of a redox electrolyte of organic or inorganic iodides (e.g., about 0.05-2 M, 0.05-1 M, or 0.05-0.5 M), and about 0.01 M to about 1 M (e.g., about 0.05-0.5 M, 0.05-0.2 M, or 0.05-0.1 M) of iodine. The ion-conducting polymer may include, for example, polyethylene oxide (PEO), polyacrylonitrile (PAN), polymethylmethacrylate (PMMA), polyethers, and polyphenols. Examples of suitable plasticizers include ethyl carbonate, propylene carbonate, mixtures of carbonates, organic phosphates, butyrolactone, and dialkylphthalates.

As discussed previously, photosensitized layer 145 includes a semiconductor material and a photosensitizing agent. These component materials can be in the form of a photosensitized nanoparticle material, a heterojunction composite material, or combinations thereof.

Suitable heterojunction composite materials include fullerenes (e.g., C₆₀), fullerene particles, or carbon nanotubes. The heterojunction composite material may be dispersed in polythiophene or some other hole transport material. In various embodiments, the heterojunction composite material includes fullerene particles and/or aggregates of fullerene particles that have an average size of between about 14 nm and 500 nm. Other examples of suitable heterojunction composite materials are composites including conjugated polymers, such as polyphenylene vinylene, in conjunction with non-polymeric materials. Typically, where photosensitized layer 145 includes a heterojunction composite material, the layer is between about 0.1 microns and about 20 microns thick.

Suitable nanoparticles include nanoparticles of the formula MₓO_{y}, where M may be, for example, titanium, zirconium, tungsten, niobium, lanthanum, tantalum, terbium, or tin and x and y are integers greater than zero. Other suitable nanoparticle materials include sulfides, selenides, tellurides, and oxides of titanium, zirconium, tungsten, niobium, lanthanum, tantalum, terbium, tin, or combinations thereof. For example, TiO₂, SrTiO₃, CaTiO₃, ZrO₂, WO₃, La₂O₃, Nb₂O₅, SnO₂, sodium titanate, cadmium selenide (CdSe), cadmium sulphides, and potassium niobate may be suitable nanoparticle materials. In various embodiments, photosensitized layer 145 includes nanoparticles with an average size between about two nm and about 100 nm (e.g., between about 10 nm and 40 nm, such as about 20 nm).

The nanoparticles can be interconnected, for example, by high temperature sintering, or by a reactive polymeric linking agent, such as poly(n-butyl titanate). A polymeric linking agent can enable the fabrication of an interconnected nanoparticle layer at relatively low temperatures (e.g., less than about 300° C.) and in some embodiments at room temperature. The relatively low temperature interconnection process may be amenable to continuous manufacturing processes using polymer substrates.

The interconnected nanoparticles are photosensitized by a photosensitizing agent. The photosensitizing agent facilitates conversion of incident light into electricity to produce the desired photovoltaic effect. It is believed that the photosensitizing agent absorbs incident light resulting in the excitation of electrons in the photosensitizing agent. The energy of the excited electrons is then transferred from the excitation levels of the photosensitizing agent into a conduction band of the interconnected nanoparticles. This electron transfer results in an effective separation of charge and the desired photovoltaic effect. Accordingly, the electrons in the conduction band of the interconnected nanoparticles are made available to drive external load 170.

The photosensitizing agent can be sorbed (e.g., chemisorbed and/or physisorbed) on the nanoparticles. The photosensitizing agent may be sorbed on the surfaces of the nanoparticles, within the nanoparticles, or both. The photosensitizing agent is selected, for example, based on its ability to absorb photons in a wavelength range of operation (e.g., within the visible spectrum), its ability to produce free electrons (or electron holes) in a conduction band of the nanoparticles, and its effectiveness in complexing with or sorbing to the nanoparticles. Suitable photosensitizing agents may include, for example, dyes that include functional groups, such as carboxyl and/or hydroxyl groups, that can chelate to the nanoparticles, e.g., to Ti(IV) sites on a TiO2 surface. Exemplary dyes include anthocyanines, porphyrins, phthalocyanines, merocyanines, cyanines, squarates, eosins, and metal-containing dyes such as cis-bis(isothiocyanato)bis(2,2′-bipyridyl-4,4′-25 dicarboxylato)-ruthenium (II) (“N3 dye”), tris(isothiocyanato)-ruthenium (II)-2,2′:6′,2″-terpyridene-4,4′,4″-tricarboxylic acid, cis-bis(isothiocyanato)bis(2,2′-bipyridyl-4,4′-dicarboxylato) ruthenium (II) bis-tetrabutylammonium, cis-bis(isocyanato) (2,2′-bipyridyl-4,4′ dicarboxylato) ruthenium (II)and tris(2,2′-bipyridyl-4,4′-dicarboxylato) ruthenium (II) dichloride, all of which are available from Solaronix.

Although, in the foregoing embodiments, the semiconductor material and electrolyte are in different layers, in some embodiments these materials may be interspersed in a composite layer.

In general, it is desirable to have good adhesion between catalyst layer 230 and surface 122. For example, the redox electrolyte solution can be corrosive to layer 230, which can result in delamination of layer 230 from surface 122 in the absence of good adhesion.

In certain embodiments, adhesion between layer 230 and surface 122 passed the tape test. As referred to herein, the tape test is conducted as follows. Layer 230 is adhered to surface 122. Tape (Magic tape, 3M) is then firmly applied to the surface of layer 230 that is opposite the surface of layer 230 that faces surface 122, and the tape is rapidly peeled off. Adhesion between layer 230 and surface 122 passes the tape test if layer 230 is not removed from surface 122 when the tape is peeled off.

In some embodiments, adhesion between layer 230 and surface 122 passed the wipe test. As referred to herein, the wipe test is conducted as follows. Layer 230 is adhered to surface 122. A tissue (Kimwipe, Kimberly-Clark) is pushed hard on the surface of layer 230 that is opposite the surface of layer 230 that faces surface 122, and the tissue is moved laterally five times while continuing to push hard. Adhesion between layer 230 and surface 122 passes the wipe test if layer 230 is not removed from surface 122 subsequent to the five lateral movements.

In certain embodiments, DSSC 200 made with an electrode containing PEDOT catalyst layer which was aged in electrolyte solution at 85° C. for at least about 100 hours (e.g., at least about 200 hours, at least about 300 hours, at least about 400 hours) can provide the same output current as an otherwise identical DSSC made from a fresh polymer catalyst layer contained electrode (e.g., the output current can vary less than about 10%).

In some embodiments, DSSC 200 can provide consistent long-term stability (e.g., the output current can vary less than about 10%) under constant ageing of cell at 65° C. for periods of 80 hours or more.

DSSC's can provide relatively efficient conversion of incident light into electrical energy. For example, DSSC's may exhibit efficiencies more than about one percent (e.g., more than about two percent, three percent, four percent, five percent, eight percent, such as ten percent or more) as measured under the sun at AM 1.5 global irradiation.

The following examples are illustrative and not intended to be limiting.

### EXAMPLE 1

0.04 gram of ethylene-dioxythiophene (EDOT) (Baytron M, Bayer) and 1.0 gram of Baytron CB-40 (Bayer, 40 weight percent iron tosylate in 1-butanol) were dissolved in 3.0 grams of 1-butanol. The resulting solution was applied on a 40 ohm/sq. ITO/PEN substrate by spin coating at 400 revolutions per minute (rpm) for 110 seconds. The coated film was heated at 120° C. for 5 minutes and subsequently cooled. The resulting PEDOT film was then washed using methanol. The PEDOT coating completely peeled off the base during washing. The transmission of film at 550 nm was 83% (about the same as a clean substrate which is 83.5%).

### EXAMPLE 2

0.04 gram of ethylene-dioxythiophene (EDOT) (Baytron M, Bayer) and 1.0 gram of Baytron CB-40 (Bayer, 40 weight percent iron tosylate in 1-butanol) were dissolved in 3.0 grams of 1-butanol. A 40 ohm/sq. ITO/PEN substrate was pretreated by 0.2M HCl ethanol solution for 5 minutes. The coating solution was applied on the pretreated substrate by spin coating at 400 rpm for 110 seconds. The coated film was heated at 120° C. for 5 minutes and subsequently cooled. The resulting PEDOT film was then washed using methanol. The PEDOT coating peeled off the base during washing. The transmission of film at 550 nm was 82.3%

### EXAMPLE 3

0.04 gram of ethylene-dioxythiophene (EDOT) (Baytron M, Bayer), 1.0 gram of Baytron CB-40 (Bayer, 40 weight percent iron tosylate in 1-butanol), and 0.05 gram of 37 weight percent hydrochloric acid were dissolved in 3.0 grams of 1-butanol. The solution was applied on a 40 ohm/sq. ITO/PEN substrate by spin coating at 500 rpm for 110 seconds. The coated film was heated at 120° C. for 5 minutes and subsequently cooled. The resulting PEDOT film was then washed using methanol. The transmission of the film at 550 nm was 78%.

### EXAMPLE 4

0.072 gram of EDOT (Baytron M, Bayer) and 0.504 gram of iron triflate were dissolved in 17.8 grams of 1-butanol. The resulting solution was applied on a 40 ohm/sq. ITO/PEN substrate by spin coating at 400 rpm for 110 seconds. The coated film was heated at 120° C. for 5 minutes and subsequently cooled. The resulting PEDOT film was then washed using methanol. The transmission of the film at 550 nm was 81%.

### EXAMPLE 5

0.028 gram of EDOT (Baytron M, Bayer) and 0.032 gram FeCl₃ were dissolved in 4.0 grams of 1-butanol. The resulting solution was applied on a 40 ohm/sq. ITO/PEN substrate by spin coating at 300 rpm for 110 seconds. The coated film was heated at 120° C. for 5 minutes and subsequently cooled. The resulting PEDOT film was then washed using methanol. The transmission of the film at 550 nm was 77%.

### EXAMPLE 6

0.04 gram of EDOT (Baytron M, Bayer), 1.0 gram Baytron CB-40 (Bayer, 40 weight percent iron tosylate in 1-butanol) and 0.033 gram of 37 weight percent hydrochloric acid were dissolved in 3.0 grams of 1-butanol. The resulting solution was applied on a 15 ohm/sq. F-doped tin oxide conducting glass by spin coating at 700 rpm for 110 seconds. The coated film was heated at 120° C. for 5 minutes and subsequently cooled. The resulting PEDOT film was then washed using methanol. The transmission of the film at 550 nm was 78.6%.

### EXAMPLE 7

0.131 gram of EDOT (Baytron M, Bayer), 3.25 grams of Baytron CB-40 (Bayer, 40 weight percent iron tosylate in 1-butanol), and 0.24 gram of 37 weight percent hydrochloric acid were dissolved in 13.6 grams of 1-butanol. The resulting solution was web coated on a 40 ohm/sq. ITO/PEN substrate at 42 milligram per square meter coverage of EDOT. The coated film was heated at 120° C. for 5 minutes and subsequently cooled. The resulting PEDOT film was then washed using methanol. The transmission of the film at 550 nm was 78.5%.

### EXAMPLE 8

0.026 gram of EDOT (Baytron M, Bayer), 0.65 gram of Baytron CB-40 (Bayer, 40 weight percent iron tosylate in 1-butanol), and 0.05 gram of 48 weight percent HBr were dissolved in 2 grams of 1-butanol. The resulting solution was applied on a 40 ohm/sq. ITO/PEN substrate by spin coating at 600 rpm for 110 seconds. The coated film was heated at 120° C. for 5 minutes and subsequently cooled. The resulting PEDOT film was then washed using methanol. The transmission of the film at 550 nm was 79.5%.

### EXAMPLE 9

0.026 gram of EDOT (Baytron M, Bayer), 0.65 gram of Baytron CB-40 (Bayer, 40 weight percent iron tosylate in 1-butanol), and 0.03 gram of 70 weight percent nitric acid were dissolved in 2 grams of 1-butanol. The resulting solution was applied on a 40 ohm/sq. ITO/PEN substrate by spin coating at 600 rpm for 110 seconds. The coated film was heated at 120° C. for 5 minutes and subsequently cooled. The resulting PEDOT film was then washed using methanol. The transmission of the film at 550 nm was 81%.

### EXAMPLE 10

0.23 g EDOT (Baytron M, Bayer), 5.5 grams of Baytron CB-40 (Bayer, 40 weight percent iron tosylate in 1-butanol), 0.1 gram gamma-glycidoxypropyltrimethoxysilane (Silquest A 187, Crompton), and 0.22 gram of 37 weight percent hydrochloric acid were dissolved in 14 grams of 1-butanol. The resulting solution was applied on a 40 ohm/sq. ITO/PEN substrate by spin coating at 600 rpm for 110 seconds. The coated film was heated at 120° C. for 5 minutes and subsequently cooled. The resulting PEDOT film was then washed using methanol. The transmission of the film at 550 nm was 81%.

### EXAMPLE 11

0.23 g EDOT (Baytron M, Bayer), 5.5 grams of Baytron CB-40 (Bayer, 40 weight percent iron tosylate in 1-butanol) and 0.22 gram of 37 weight percent hydrochloric acid were dissolved in 14 grams of 1-butanol. The resulting solution was applied either on 15 ohm/sq. fluorine-doped tin oxide glass (TEC15) or 15 ohm/sq. ITO/glass substrate by spin coating at 600 rpm for 110 seconds. The coated films were heated at 120° C. for 5 minutes and subsequently cooled. The resulting PEDOT film was then washed using methanol. DSSCs made from these two types of PEDOT counter electrodes. The long-term stability of DSSC made from the PEDOT coated TEC15 counter electrode showed that the cell efficiency of conversion of light to electricity decreased 9% under constant ageing of cell at 80° C. for periods of 800 hours. The long-term stability of the DSSC made from the PEDOT coated ITO/glass counter electrode showed that the cell efficiency decreased 35% under constant ageing of cell at 80° C. for periods of 800 hours.

The lower transmission observed in Examples 3-10 relative to Example 1 indicated that improved adhesion of the PEDOT layer was obtained in Examples 3-10 relative to Example 1. The lower transmission observed in Examples 3-10 relative to Example 2 indicated that improved adhesion of the PEDOT layer was obtained in Examples 3-10 relative to Example 2.

The PEDOT layers in Examples 3-11 passed the tape test and the wipe test.

The PEDOT coatings from Examples 3 through 11 provided substantially the same catalytic activity when used as a counter electrode in a DSSC. When used as a counter electrode in a DSSC, the PEDOT coatings from Examples 3 through 11 provided comparable catalytic activity to that provided by a platinum counter electrode in a DSSC.

Other embodiments are in the claims.

1. A composition, comprising:
a monomer capable of forming a polymer capable of catalyzing reduction of I₃⁻ to I⁻;
a solvent; and
an acid, wherein
the acid has a pKa of about three or less.

2. The composition of claim 1, wherein the acid has a pKa of about two or less.

3. The composition of claim 1, wherein the acid has a pKa of about one or less.

4. The composition of claim 1, wherein the acid has a pKa of about zero or less.

5. The composition of claim 1, wherein the acid comprises an inorganic acid.

6. The composition of claim 5, wherein the inorganic acid comprises hydrochloric acid, nitric acid, perchloric acid, chloric acid, hydrogen iodide, hydrogen bromide, or thiocyanic acid.

7. The composition of claim 1, wherein the acid comprises an organic acid.

8. The composition of claim 7, wherein the organic acid comprises trifluoromethanesulfonic acid, benzenesulfonic acid, methanesulphonic acid, p-toluenesulfonic acid, or tricyanomethane.

9. The composition of claim 1, wherein the composition comprises at least about 0.01 molar acid.

10. The composition of claim 1, wherein the composition comprises at least about 0.05 molar acid.

11. The composition of claim 1, wherein the composition comprises at least about 0.1 molar acid.

12. The composition of claim 9, wherein the composition comprises about 0.2 molar or less acid.

13. The composition of claim 1, wherein the monomer comprises a thiophene monomer.

14. The composition of claim 13, wherein the thiophene monomer comprises ethylene dioxythiophene.

15. The composition of claim 1, wherein the polymer is transparent.

16. The composition of claim 1, wherein the solvent comprises a polar organic solvent.

17. The composition of claim 16, wherein the polar organic solvent comprises an alcohol, a sulphoxide, a sulphone, an amide or a nitrile.

18. The composition of claim 16, wherein the organic solvent comprises methanol, ethanol, i-propanol, dichloromethane, dichloroethane, acetonitrile, dimethyl sulphoxide, sulfolane, methyl acetamide, or dimethyl formamide.

19. The composition of claim 1, wherein the solvent comprises water.

20. The composition of claim 1, further comprising an initiator capable of causing the monomer to react to form the polymer.

21. The composition of claim 1, wherein the initiator comprises an oxidant.

22. The composition of claim 21, wherein the oxidant comprises an iron (II) salt, H₂O₂, K₂Cr₂O₇, alkali metal persulphates, ammonium persulphates, alkali metal perborates, potassium permanganate or copper salts.

23. The composition of claim 21, wherein the oxidant comprises an iron (III) salt.

24. The composition of claim 23, wherein the iron (III) salt comprises FeCl₃, Fe(ClO₄)₃ or iron (III) salts of organic acids.

25. The composition of claim 23, wherein the iron (III) salt comprises iron (III) tosylate.

26. The method of claim 1, wherein a ratio of a molar concentration of the monomer to a molar concentration of the initiator in the composition is equal to or less than about five.

27. A composition, comprising:
a monomer capable of forming a polymer capable of catalyzing reduction of I₃⁻ to I⁻;
a solvent; and
an acid,
wherein the composition comprises at least about 0.01 molar acid.

28. The composition of claim 27, wherein the composition comprises at least about 0.05 molar acid.

29. The composition of claim 27, wherein the composition comprises at least about 0.1 molar acid.

30. The composition of claim 27, wherein the composition comprises about 0.2 molar or less acid.

31. A method, comprising:
disposing a composition on a surface,
wherein:
the composition comprises a monomer capable of forming a polymer capable of catalyzing reduction of I₃⁻ to I⁻, a solvent, and an acid; and
the acid has a pKa of about three or less.

32. The method of claim 31, wherein the surface is an electrically-conductive surface.

33. The method of claim 31, wherein the surface is a surface of a transparent layer.

34. The method of claim 33, wherein the transparent layer is electrically-conductive.

35. The method of claim 33, wherein the transparent layer comprises a mesh.

36. The method of claim 33, wherein the transparent layer comprises at least one member selected from the group consisting of ITO, tin oxide and fluorine-doped tin oxide.

37. The method of claim 31, wherein disposing the solution on the surface comprises coating the composition on the surface.

38. The method of claim 37, wherein coating comprises spin coating, dip coating, knife coating, bar coating, spray coating, roller coating, slot coating, gravure coating, or screen printing.

39. The method of claim 31, further comprising electrochemically depositing the polymer on the surface.

40. The method of claim 31, further comprising polymerizing the monomer after disposing the solution on the surface to form a layer on the surface comprising the polymer.

41. The method of claim 40, wherein polymerizing the monomer comprises heating the surface after disposing the solution on the surface.

42. The method of claim 41, wherein the surface is heated above about 50° C.

43. The method of claim 41, wherein the surface is heated above about 100° C.

44. The method of claim 40, wherein the layer is less than about 100 nm thick.

45. The method of claim 40, wherein the layer is less than about 50 nm thick.

46. The method of claim 31, further comprising washing the surface after forming the layer, wherein during the washing the polymer remains substantially adhered to the surface.

47. The method of claim 46, wherein washing the surface comprises exposing the layer to a washing solvent.

48. The method of claim 47, wherein the washing solvent comprises a polar solvent.

49. The method of claim 48, wherein the polar solvent comprises water or an alcohol.

50. The method of claim 47, wherein washing the surface comprises agitating the surface while exposing the layer to the washing solvent.

51. The method of claim 31, wherein the polymer comprises a polythiophene.

52. The method of claim 51, wherein the polythiophene comprises polyethylene dioxythiophene.

53. A method, comprising:
disposing a composition on a surface,
wherein:
the composition comprises a monomer capable of forming a polymer capable of catalyzing reduction of I₃⁻ to I⁻, a solvent, and an acid; and
the composition comprises at least 0.01 molar acid.

54. A method, comprising:
coating an electrically conductive surface with a composition,
wherein the composition comprises a monomer capable of forming a polymer capable of catalyzing reduction of I₃⁻ to I⁻, a solvent, and an acid.

55. An article, comprising:
a first layer having a surface, the first layer comprising an electrically conductive material; and
a second layer disposed on the surface of the first layer, the second layer comprising a polymer capable of catalyzing reduction of I₃⁻ to I⁻,
wherein the second layer remains disposed on the surface of the first layer after washing the second layer.

56. The article of claim 55, wherein the article is an electrode.

57. The article of claim 56, wherein the electrode is a counter-electrode of a photovoltaic cell.

58. The article of claim 55, wherein the first layer is transparent.

59. The article of claim 55, wherein the electrically conductive material comprises at least one member selected from the group consisting of ITO, tin oxide and fluorine-doped tin oxide.

60. The article of claim 55, further comprising a substrate layer, wherein the first layer is disposed on the substrate layer.

61. The article of claim 60, further comprising at least one layer between the substrate layer and the first layer.

62. The article of claim 60, wherein the substrate layer comprises a polymer.

63. The article of claim 62, wherein the polymer comprises polyethylene naphthalate, polyethylene terephthalate, polyethyelene, polypropylene, polymethylmethacrylate, polycarbonate, or polyurethane.

64. The article of claim 60, wherein an adhesion of the second layer to the first layer is greater than an adhesion of the first layer to the substrate layer.

65. The article of claim 55, wherein the second layer is about 100 nm or less thick.

66. The article of claim 65, wherein the second layer is about 50 nm or less thick.

67. The article of claim 55, wherein the polymer comprises a polythiophene.

68. The article of claim 67, wherein the polythiophene comprises PEDOT.

69. The article of claim 55, wherein the second layer is transparent.

70. A photovoltaic cell, comprising:
a first electrode;
a second electrode, comprising:
an electrically conductive layer having a surface; and
a second layer disposed on the surface of the electrically conductive layer, the second layer comprising a polymer capable of catalyzing reduction of I₃⁻ to I⁻; and
a third layer comprising an electrolyte disposed between the first electrode and the second electrode,
wherein the second layer remains disposed on the surface of the electrically conductive layer after washing the second layer.
